(19) United States
(12) Patent Application Publication
(10) Pub. No.: US 2024/0021487 A1
(43) Pub. Date: Jan. 18, 2024

(54) SEMICONDUCTOR DEVICE PACKAGE

(71) Applicant: SEMICONDUCTOR COMPONENTS INDUSTRIES, LLC, Scottsdale, AZ (US)

(72) Inventors: Jie CHANG, Suzhou (CN); XiaoYing YUAN, Suzhou (CN); Keunhyuk LEE, Suzhou (CN); Paolo BILARDO, Munich (DE)

(73) Assignee: SEMICONDUCTOR COMPONENTS INDUSTRIES, LLC, Scottsdale, AZ (US)

(21) Appl. No.: 18/349,440

(22) Filed: Jul. 10, 2023

Related U.S. Application Data
(60) Provisional application No. 63/368,202, filed on Jul. 12, 2022.

(51) Int. Cl. H01L 23/31; H01L 23/495; H01L 23/498; H01L 23/367; H01L 21/56

(52) U.S. Cl. CPC H01L 23/3107; H01L 23/4951; H01L 23/49844; H01L 23/3675; H01L 21/565

(57) ABSTRACT

A package includes a semiconductor die attached to a substrate and a molded body encapsulating the semiconductor die. The molded body is a six-sided rectangular box-like structure and at least a corner portion of the molded body formed by two adjacent sides is devoid of molding material reducing a size and a weight of the molded body.

### RELATED APPLICATION

This application claims priority to and the benefit of U.S. Provisional No. 63/368,202, filed on Jul. 12, 2022, which is incorporated by reference in its entirety herein. This application is also related to commonly assigned U.S. patent application Ser. No. 18/185,514, titled “DISCRETE SEMICONDUCTOR DEVICE PACKAGE,” filed on Mar. 17, 2023, which is incorporated by reference in its entirety herein.

### TECHNICAL FIELD

This description relates to packaging of semiconductor die and integrated circuits.

### BACKGROUND

A semiconductor package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The package provides a means for connecting the semiconductor devices or integrated circuits to the external environment, such as printed circuit board, via leads such as lands, balls, or pins; and protection against threats such as mechanical impact, chemical contamination, and light exposure. With increasing demand for high-performance ICs, new improvements are needed in packaging technologies to bring out the ICs' performance and reliability.

### SUMMARY

In a general aspect, a package includes a semiconductor die attached to a substrate and a molded body encapsulating the semiconductor die. The molded body is a six-sided rectangular box-like structure and at least a corner portion of the molded body formed by two adjacent sides is devoid of molding material reducing a size and a weight of the molded body.

In a further aspect, a top surface of the molded body includes a heat dissipating surface. The semiconductor die encapsulated in the molded body is thermally coupled to the heat dissipating surface.

In a general aspect, a package includes a semiconductor die attached to a substrate and a molded body encapsulating the semiconductor die. The molded body encapsulating the semiconductor die is a six-sided rectangular box-like structure. At least a lead is attached the semiconductor die with a portion of the lead extending to an outside of the molded body and forming an external terminal of the package. The lead is a drain contact lead and a portion of the drain contact lead extending to the outside of the molded body is notched to reduce a strength of the drain contact lead.

In a general aspect, a method for fabricating a package includes disposing a semiconductor die on a substrate (e.g., a lead frame substrate), and encapsulating the semiconductor die in a molded body. The molded body is a six-sided rectangular box-like structure. At least a corner portion of the molded body formed by two adjacent sides is devoid of molding material reducing a size and a weight of the molded body.

In a general aspect, a method for fabricating a package includes disposing a semiconductor die on a substrate (e.g., a lead frame substrate), and encapsulating the semiconductor die in a molded body. The molded body is a six-sided rectangular box-like structure. The method further includes attaching a drain contact lead to the semiconductor die. A portion of the drain contact lead extends to an outside of the molded body and forms an external terminal of the package. The method further includes notching the portion of the drain contact lead extending to an outside of the molded body to reduce a strength of the drain contact lead.

The details of one or more implementations are set forth in the accompanying drawings and the description below. Other features will be apparent from the description and drawings, and from the claims.

### BRIEF DESCRIPTION OF THE DRAWINGS

FIG. 1A illustrates an example semiconductor device package.

FIG. 1B illustrates a footprint of the semiconductor device package of FIG. 1A.

FIG. 2A, FIG. 2B, FIG. 2C, and FIG. 2D illustrate exterior views of an example semiconductor device package with a structure configured to resist stress-induced cracking of a molded body of the package.

FIG. 3A, FIG. 3B, FIG. 3C, and FIG. 3D illustrate exterior views of another example semiconductor device package with a structure configured to resist stress-induced cracking of the molded body of the package.

FIG. 4, FIG. 5, and FIG. 6 illustrate examples of semiconductor die that may be enclosed in molded body of the semiconductor device package of FIG. 2A or in molded body of semiconductor device package of FIG. 3A.

FIG. 7 illustrates an example method for fabricating a semiconductor device package.

FIG. 8 illustrates another example method for fabricating a semiconductor device package.

### DETAILED DESCRIPTION

A semiconductor device package (e.g., an integrated circuit (IC) package) includes a semiconductor die mounted on a lead frame structure that includes leads providing external electrical connections (external to the package) for individual devices or integrated circuits in the semiconductor die. The semiconductor die can be mounted on a paddle or flag in the leadframe structure using a solder or a conductive adhesive. Further, device contact pads on the semiconductor die are electrically connected using wire bonds (e.g., aluminum wire bonds) to respective ones of the leads. The leads, which extend to an outside of the package body, form external terminal pins that can be used to mount the package on a printed circuit board or terminal strip. In example implementations, the terminal pins can be installed in sockets or soldered to a printed circuit board (PCB) or terminal strip.

There can be many package types used in various applications. Some are defined by international, national, or industry standards, while others are particular to an individual manufacturer. The number and configuration of external terminal pins of a package type may be defined by international, national, or industry standards. A standardized semiconductor device package type can be intended for surface mounting on circuit boards (e.g., a printed circuit board (PCB)). In an example semiconductor device package, the pins on the package are bent to lie against the PCB surface. The package can, for example, have three to seven signal terminals in addition to tabs for power input and output. For automotive applications, the semiconductor package may include silicon carbide transistors, gallium nitride devices, or insulated gate bipolar transistor (IGBT), fast recovery diode (FRD), silicon carbide diode, or other devices.

The device and other components (e.g., a lead frame substrate) of a semiconductor package may be encapsulated in a molding material body (e.g., body made of a plastic or an epoxy, etc.). Pins or terminals (e.g., signal pins, power terminals) may extend to outside the package body. In an example implementation, a semiconductor device package excluding pins can, for example, be a rectangular box-like structure with a width W, a height H, and a length L.

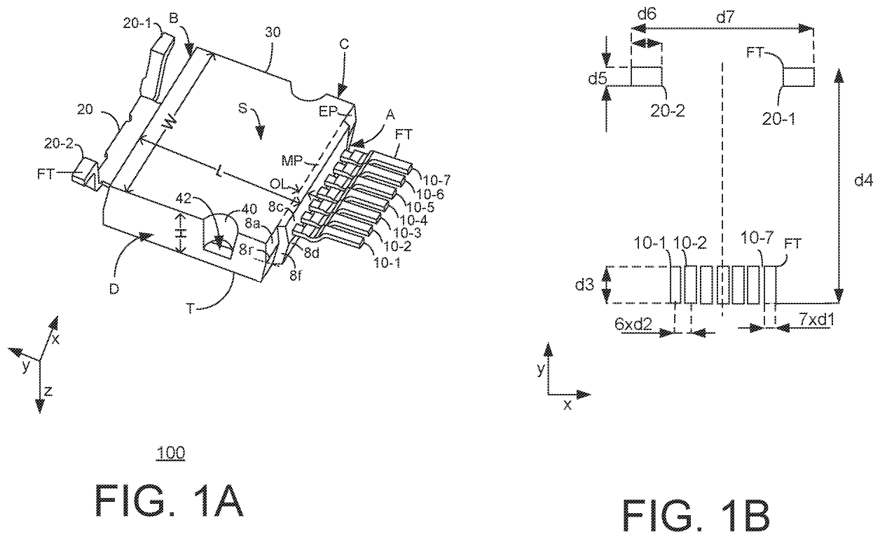

FIG. 1A shows a perspective view of a semiconductor device package 100. Semiconductor device package 100 includes a molded body 30 made of a plastic or an epoxy, etc. Molded body 30 may be made of a plastic material. Molded body 30 may enclose a semiconductor device or circuit (not visible). Molded body 30 may have a generally six-sided rectangular box-like shape with opposing side A and side B, opposing side C and side D, and opposing top side T and a bottom side S.

Molded body 30 may enclose a semiconductor device or circuit (not visible). Lead frames (leads) connected to the enclosed semiconductor device of circuit may extend to the outside of the molded body to form the external terminals of the enclosed semiconductor device or circuit. The leads may be made of metal or metal alloys (e.g., copper). In the example shown in FIG. 1A, seven signal leads (e.g., leads 10-2, 10-3, 10-4, 10-5, 10-6, and 10-7), for example, extend out from a side (e.g., side A) of molded body 30, and a power lead 20 (e.g., a drain lead) extends out from an opposite side (e.g., side B) of molded body 30. The seven signal leads may be formed by rectangular strips of metal. The power lead 20 may be shaped as a metal plate or metal strip which extends outside molded body into to form a U-shape connector with side wings having end tips 20-1, 20-2. In example implementations, the signal leads (e.g., leads 10-1, 10-2, 10-3, 10-4, 10-5, 10-6, and 10-7) and the end tips 20-1, 20-2 of the power lead (e.g., a drain lead) may be shaped as, or include flat surfaces FT that can be evenly placed on a printed circuit board surface for connection (e.g., soldering) of semiconductor device package 100 to the printed circuit board.

In example implementations, molded body may include cutouts (e.g., cutout 40) (e.g., a half-cylindrical cutout) extending from opposing bottom side S and toward top side T along the opposing sides C and D. A bottom of cutout 40 may form a clamping surface 42 that can be used, for example, to hold semiconductor device package 100 on the printed circuit board with a clamp (not shown).

In example implementations, the box-like structure of molded body 30 may have dimensions: W=about 20 mm; L=about 28 mm; and height H=about 4 mm. FIG. 1B illustrates an example footprint map of semiconductor device package 100 showing example dimensions of the flat surfaces FT of the signal leads (e.g., leads 10-1, 10-3, 10-4, 10-5, 10-6, and 10-7) and the end tips 20-1, 20-2 of the power lead. In FIG. 1B, the example distances and sizes of example semiconductor device package 100 are marked or indicated in millimeters.

In a semiconductor device package, a coefficient of thermal expansion (CTE) mismatch between the semiconductor die and the lead frame (e.g., a copper lead frame) or CTE mismatch between a clip (e.g., a copper clip) and the semiconductor die can introduce high stress on the solder between the components. Cracks may be observed after temperature cycling. Further, wire fatigue (of an aluminum wire connecting a gate of the semiconductor die and the lead frame) can be a weakness in a typical package during power cycles.

Further, a coefficient of thermal expansion (CTE) mismatch between components of the semiconductor device package and the molded body of the semiconductor device package can lead to physical deterioration (e.g., cracks) of the molded body encapsulating the components.

The packaging implementations described herein address these issues and provide a cost effective and reliable solution for packaging a semiconductor die (e.g., a power transistor, a silicon carbide (SiC) MOSFET, or another device).

In accordance with the principles of the present disclosure, in example packaging implementations, a molded body and the leads of a semiconductor device package are shaped and structured to avoid stress-induced cracking of the molded body (e.g., under temperature cycling).

In example implementations, a molded body that is shaped and structured to avoid stress-induced cracking may include one or more of the following features:
a. A notched drain lead. A notch in the drain lead can reduce the strength of the drain lead and reduce the stress caused by the drain lead on the printed circuit board.
b. Reduced molded body size and weight. The molded body may be shaped to exclude mold material, for example, at the corners next to the signal leads and/or at the corners next to the drain leads.
c. Disposing a wide slot on an edge of a surface of the molded body to increase a creepage distance to the signal leads.
d. Shorter drain lead. A shorter drain lead can enable high unit density lead frame design.
e. Symmetrically located clamping surfaces. Symmetrically located clamping surfaces may enable balanced clamping of the device package on a printed circuit board.

Further, in accordance with the principles of the present disclosure, in example packaging implementations, a top surface of the molded body includes a surface of a heat sink coupled to the semiconductor die enclosed in the molded body.

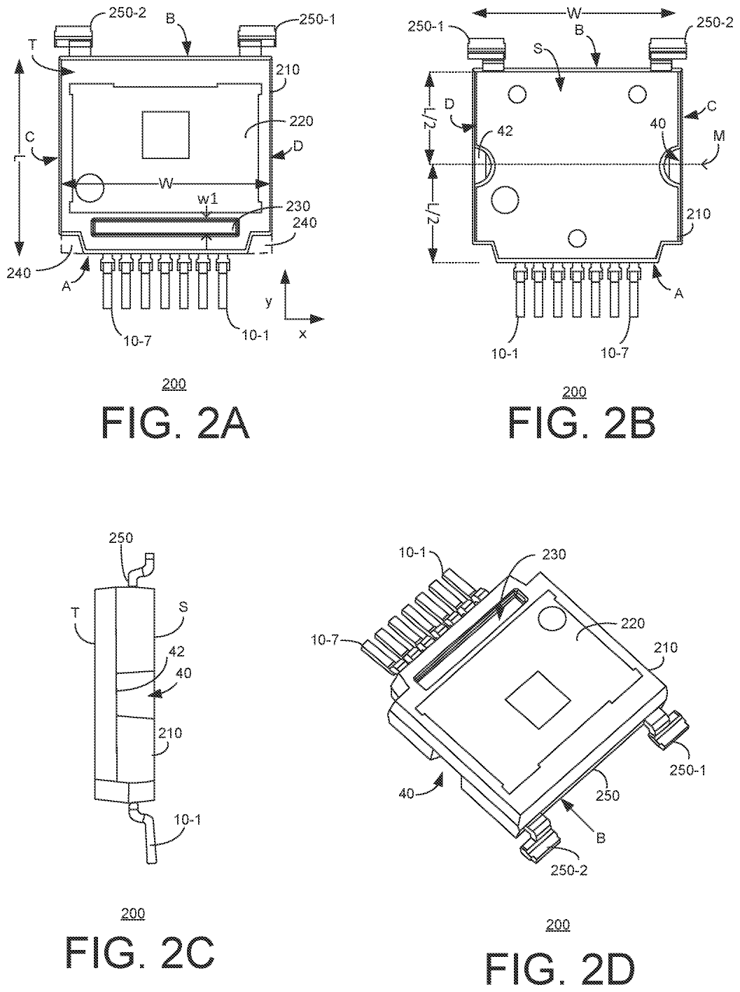

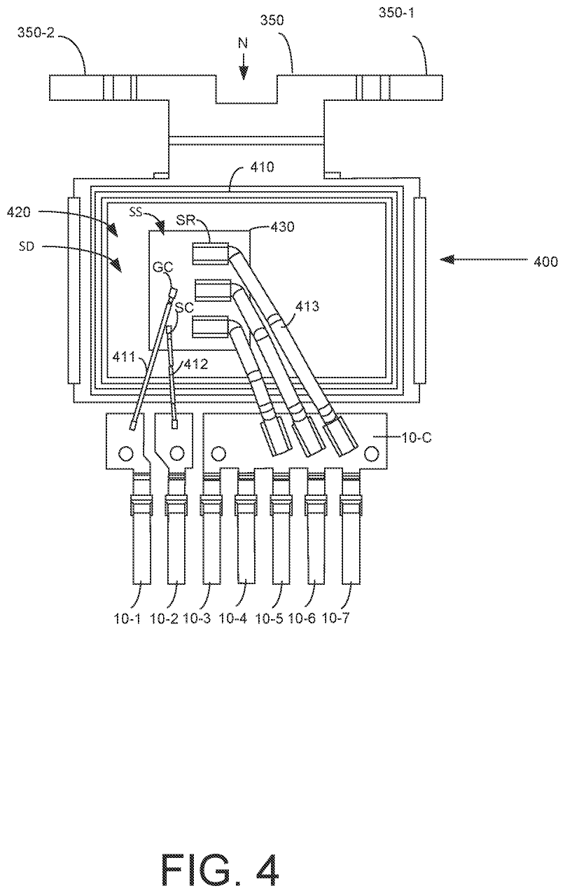

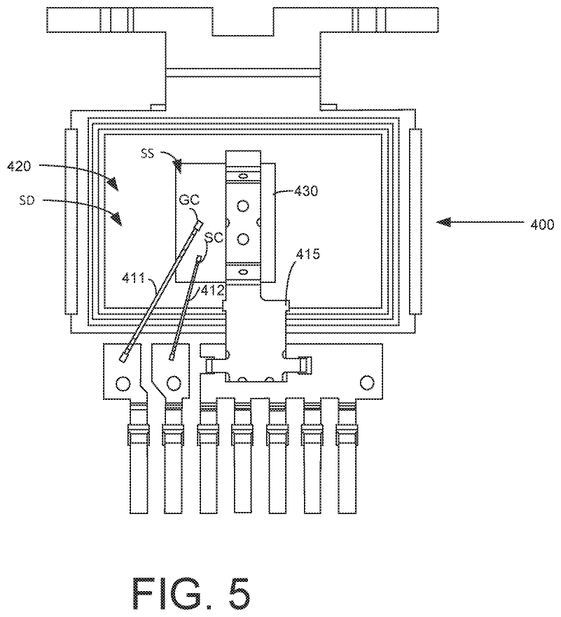

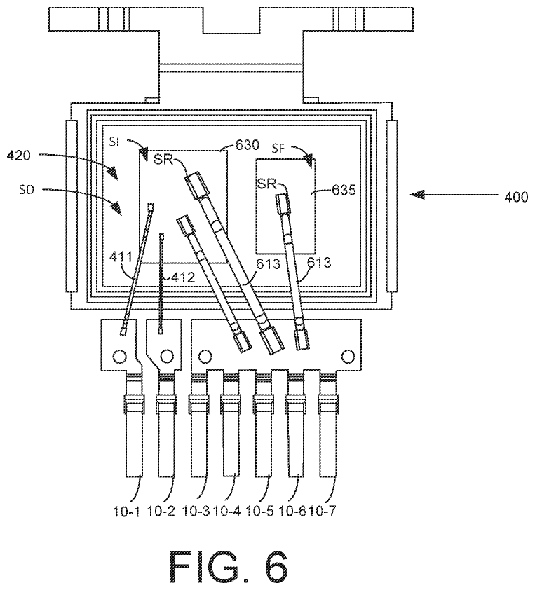

FIG. 2A through FIG. 2D illustrate exterior views of an example semiconductor device package 200 with a structure configured to resist stress-induced cracking of the molded body of the package. Semiconductor device package 200 includes a molded body 210. Semiconductor devices or circuits that may be enclosed in the molded body 210 are not visible in FIGS. 2A through 2D, but are shown, for example, in FIGS. 4 to 6. FIG. 2A shows a top plan view; FIG. 2B shows a bottom plan view; FIG. 2C shows a side view; and FIG. 2D shows a top perspective view of semiconductor device package 200.

As shown in FIG. 2A through FIG. 2D, molded body 210 can have a six-sided rectangular box-like shape with four vertical sides (sides A. B. C and D), a top side T and a bottom side S. The top side and bottom side may have a length L and a width W. Further, signal leads (e.g., lead 10-1, . . . lead 10-7) extend to the outside of molded body through side A, and a drain lead 250 extends to the outside of molded body through side B. As shown in FIG. 2D, drain lead 250 may be shaped a plate of metal trip. Drain lead is short so that most of drain lead 250 is inside the molded body and only end tips 250-1 and 250-2 protrude substantially from the molded body.

Further, in example implementations, as shown in FIG. 2A and FIG. 2D, a wide slot (e.g., slot 230) may be disposed in molded body 210 (e.g., along or aligned with side A). Slot 230 (e.g., of width w1 and depth d1) may increase a creepage distance to the signal leads protruding from side A.

Further, in example implementations, molded body 210 may be shaped (i.e., fabricated) to exclude mold material, for example, at the corner formed by sides A and C and the corner formed by sides A and D (e.g., corner 240) next to the signal leads (e.g., leads 10-1 to 10-7). This exclusion may reduce the amount (e.g., weight) of mold material included in molded body 210.

In example implementations, a top surface of molded body 210 includes a surface 220 of a heat sink thermally coupled to the semiconductor die enclosed in the molded body.

Further, in example implementations, molded body 210 may include cutouts (e.g., cutout 40) extending from opposing bottom side S and toward top side T along the opposing sides C and D. A bottom of cutout 40 may form a clamping surface 42 that can be used, for example, to hold semiconductor device package 100 on the printed circuit board with a clamp (not shown). As shown in FIG. 2B, cutouts 40 and clamping surfaces 42 may be formed along an x axis (e.g., axis M) that is midway (e.g., about equidistant) from side A and side B. This location of the clamping surfaces may enable balanced clamping of semiconductor device package 200 on a printed circuit board.

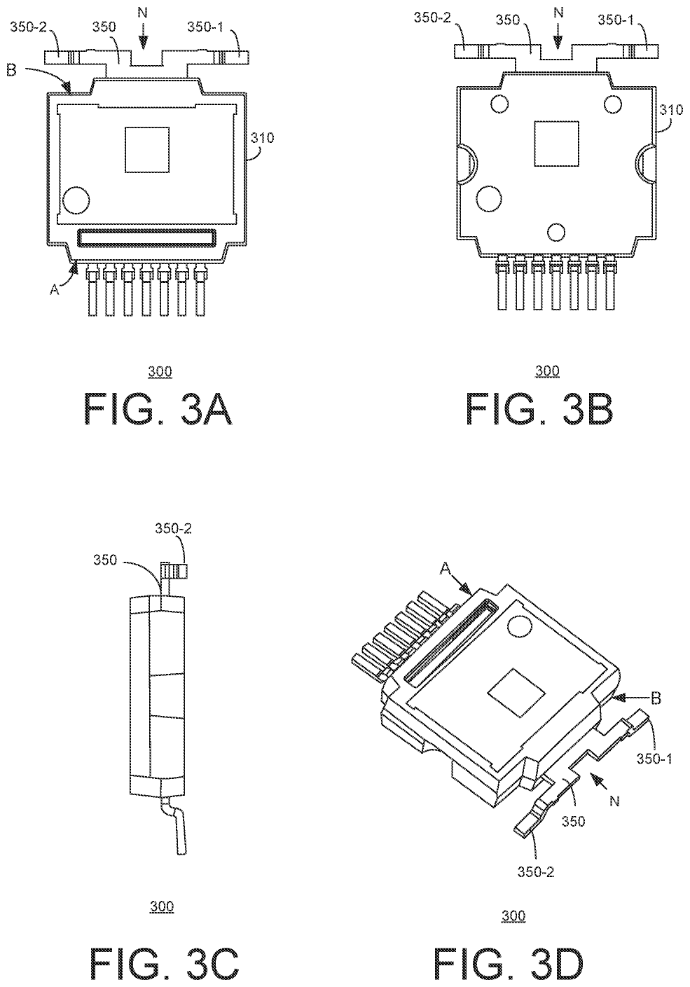

FIG. 3A-through FIG. 3D illustrate exterior views of another example semiconductor device package 300 with a structure configured to resist stress-induced cracking of the molded body of the package. Semiconductor device package 300 includes a molded body 310. Semiconductor devices or circuits that may be enclosed in the molded body 310 are not visible in FIGS. A-through 3D, but are shown, for example, in FIGS. 4 to 6. FIG. 3A shows a top plan view; FIG. 3B shows a bottom plan view; FIG. 3C shows a side view; and FIG. 3D shows a top perspective view of semiconductor device package 200. As shown in FIG. 3A through 3D, molded body 310 (like molded body 210, FIG. 2A through 2D) can have a six-sided rectangular box-like shape with four vertical sides (sides A. B. C and D), a top side T and a bottom side S. The top side and bottom side may have a length L and a width W. Further, signal leads (e.g., lead 10-1, . . . lead 10-7) extend to the outside of molded body through side A, and a drain lead 350 extends to the outside of molded body through side B and branches into a pair of end tips (e.g., end tip 350-1 and 350-2). As shown in FIG. 3D, a portion of drain lead 350 extending out of side B of the molded body 310 is notched (e.g., by notch N) before drain lead 250 branches into end tips 350-1 and 350-2. Notch N may reduce a strength of drain lead 250 and reduce a stress on a printed circuit board on which semiconductor device package 300 is mounted. This may avoid cracking of the molded body during temperature cycling of semiconductor device package 300.

FIG. 4 through FIG. 6 illustrate examples of semiconductor die that may be enclosed in molded body 210 of semiconductor device package 200 (FIG. 2A) or in molded body 310 of semiconductor device package 300 (FIG. 3A).

FIG. 4 shows an example a semiconductor die 430 (e.g., a 1200V SiC MOSFET, maximum current ˜600A, power ˜500 KW) that may be encapsulated in a molded body (e.g., molded body 310). Semiconductor die 430 may be disposed on a die attach pad (e.g., DAP 420) on a top surface SD of a lead frame substrate (e.g., substrate 400) in the package. Substrate 400 may be made of metal (e.g., copper). In some example implementations, semiconductor die 430 may be attached to DAP 420 by a solder. In some other example implementations, semiconductor die 430 may be attached to DAP 420 by a sinter (e.g., a silver-based sinter, (e.g., Ag sinter)). Substrate 400 may include a header portion (e.g., header 410) above (e.g., in the y direction) DAP 420. On one side, header portion (e.g., header 410 may be electrically connected through the substrate to DAP 420. On another side, header 410 may connect to or extend into drain lead 350 extending out of side B of the molded body 310.

A top surface SS of semiconductor die 430 may include device contact pads (e.g., gate contact pad GC, sense contact pad SC, and several (e.g., three) source contact pads SR). In some instances, wire bonding can be used to connect the device contact pads on semiconductor die to the signal leads (e.g., lead 10-1 . . . lead 10-7) of semiconductor device package 300. As shown for example in FIG. 4, the gate contact pad GC and the sense contact pad SC may be connected to leads 10-1 and lead 10-2 by wires (e.g., wire 411 and wire 412). In some other instances, high current carrying capacity wires (e.g., bonded aluminum wires) can be used to attach leads forming the external terminals of the package to the device contact pads (e.g., source, gate, sense, and drain contact pads) on the semiconductor die. In example implementations, some of the leads may share common lead portions or extensions. For example, as shown in FIG. 4, several leads (e.g., lead 10-3, lead 10-4, lead 10-5, lead 10-6, and lead 10-7) are connected to, and share, a common lead extension (i.e., source lead extension 10-C).

As shown for example in FIG. 4, the three source contact pads SR may be connected to a combination of signal leads (e.g., lead 10-3 through lead 10-7 connected as source lead extension 10-C) by bonded aluminum wire (e.g., wire 413).

In some other instances, a direct lead attach (DLA) process can be used to attach leads forming the external terminals of the semiconductor device package directly (e.g., in direct contact without a wire connection or other intervening element) to the device contact pads (e.g., source, gate, sense, and drain contact pads) on the semiconductor die. A direct lead attach (DLA) clip with preformed leads can be used to connect, for example, the device contact pads on the semiconductor die to the signal leads.

FIG. 5 shows an example, in which a DLA clip (clip 415) connects the source contact pads on semiconductor die 430 to source lead extension 10-C) (instead of the aluminum wire shown in FIG. 4). It is noted that the three source contact pads SR shown in FIG. 4 are not visible in FIG. 5 as they are hidden under DLA clip (clip 415).

In some example implementations, multiple semiconductor die may be enclosed in molded body 210 or molded body 310. The multiple semiconductor die may, for example, include two semiconductor dies (e.g., an IGBT die and a FRD die).

FIG. 6 shows, for example, a first second semiconductor die (e.g., IGBT die 630) and a second semiconductor die (e.g., FRD die 635) that may be encapsulated in a molded body (e.g., molded body 310). The first semiconductor die (e.g., IGBT die 630) and a second semiconductor die (e.g., FRD die 635, or a silicon carbide diode) may be disposed on the die attach pad (e.g., DAP 420) on a top surface SD of the lead frame substrate (e.g., substrate 400) in the semiconductor device package. In some other example implementations, IGBT die 630 and FRD die 635 may be attached to DAP 420 by a sinter (e.g., a silver-based sinter, (e.g., Ag sinter). In some other example implementations, IGBT die 630 and FRD die 635 may be attached to DAP 420 by a solder.

A top surface SI of IGBT die 630 may include device contact pads (e.g., gate contact pad GC, sense contact pad SC, and two source contact pads SR). A top surface SF of FRD die 635 may include device contact pads (e.g., a single source contact pad SR).

In example implementations, the gate contact pad GC and the sense contact pad SC of IGBT die 630 may be connected to leads 10-1 and lead 10-2 by wires (e.g., wire 411 and wire 412). Further, the two source contact pads SR of IGBT die 630 and the single source contact pad SR of FRD die 635 may be connected to a combination of signal leads (e.g., lead 10-3 through lead 10-7 connected as source lead extension 10-C) by bonded aluminum wire (e.g., wire 613).

In example implementations, a spacer block (e.g., a metal spacer block) may be thermally coupled to the top surfaces of the semiconductor die (e.g., semiconductor die 430, IGBT die 630, FRD die 635, etc.) enclosed in the semiconductor device packages. The spacer block may be coupled to a heat dissipating surface (e.g., a metal surface) enclosed in the top surface of the molded body in the semiconductor device packages described herein (in other words, the semiconductor die may be thermally coupled to the heat dissipating surface in the top surface of the molded body.

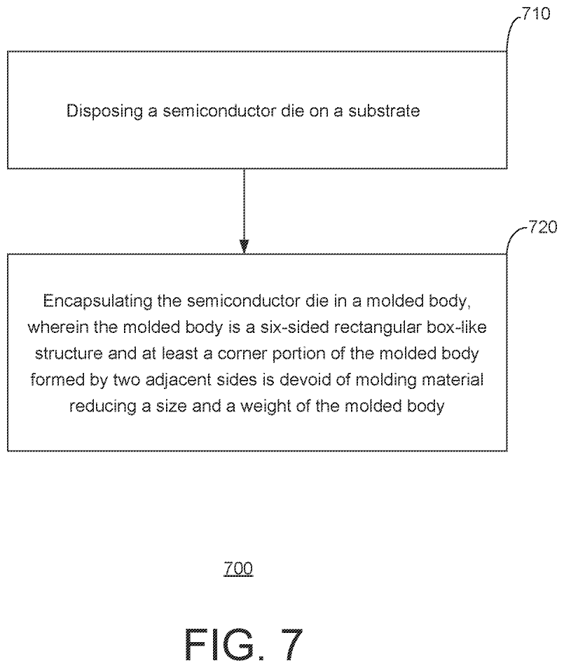

FIG. 7 illustrates an example method 700 for fabricating a semiconductor device package.

Method 700 includes disposing a semiconductor die on a substrate (710), and encapsulating the semiconductor die in a molded body (720). The molded body may be a six-sided rectangular box-like structure and at least a corner portion of the molded body formed by two adjacent sides is devoid of molding material reducing a size and a weight of the molded body.

Method 700 may further include disposing a heat dissipating surface in a top surface of the molded body, and thermally coupling the semiconductor die encapsulated in the molded body to the heat dissipating surface.

Method 700 may further include attaching a drain contact lead to the semiconductor die with a portion of the drain contact lead extending to an outside of the molded body and forming an external terminal of the package, and notching the portion of the drain contact lead extending to an outside of the molded body to reduce a strength of the drain contact lead.

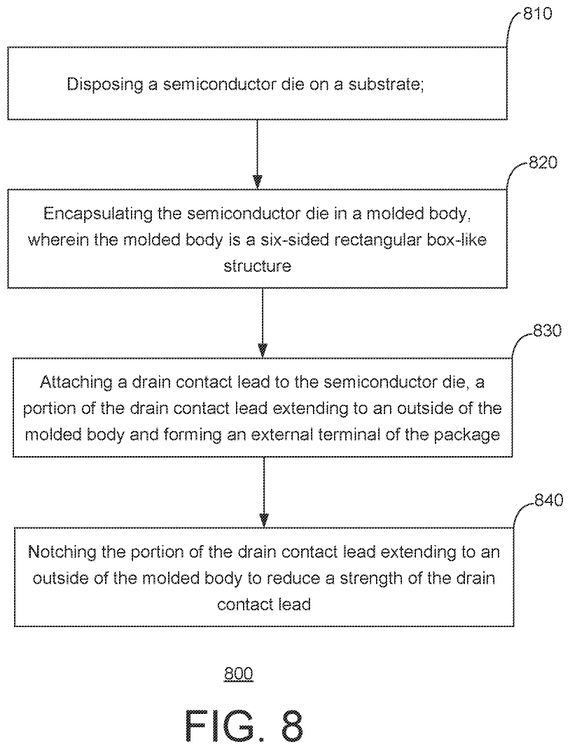

FIG. 8 illustrates an example method 800 for fabricating a semiconductor device package.

Method 800 includes disposing a semiconductor die on a substrate (810), and encapsulating the semiconductor die in a molded body (820). The molded body can be a six-sided rectangular box-like structure. Method 800 further includes attaching a drain contact lead to the semiconductor die with a portion of the drain contact lead extending to an outside of the molded body and forming an external terminal of the package (830), and notching the portion of the drain contact lead extending to an outside of the molded body to reduce a strength of the drain contact lead (840).

Method 800 further includes disposing a heat dissipating surface in a top surface of the molded body, and thermally coupling the semiconductor die encapsulated in the molded body to the heat dissipating surface.

In method 800, encapsulating the semiconductor die in the molded body 820 includes excluding mold material from at least a corner portion of the molded body formed by two adjacent sides to reduce a size and a weight of the molded body.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A package comprising:
a semiconductor die attached to a substrate; and
a molded body encapsulating the semiconductor die, wherein the molded body is a six-sided rectangular box-like structure and at least a corner portion of the molded body formed by two adjacent sides is devoid of molding material reducing a size and a weight of the molded body.

2. The package of claim 1, wherein a top surface of the molded body includes a heat dissipating surface, and wherein the semiconductor die encapsulated in the molded body is thermally coupled to the heat dissipating surface.

3. The package of claim 1, further comprising:
at least a lead attached to the semiconductor die, a portion of the lead extending to an outside of the molded body and forming an external terminal of the package, wherein the lead is a drain contact lead and a portion of the drain contact lead extending to the outside of the molded body is notched to reduce a strength of the drain contact lead.

4. The package of claim 1, further comprising:
at least a lead attached to a device contact pad on the semiconductor die, a portion of the lead extending to an outside the molded body and forming an external terminal of the package, wherein the lead is a drain contact lead shaped as a metal plate which extends to form a U-shape connector with side wings having end tips, wherein only the side wings having the end tips of the drain contact lead extend to the outside of the molded body.

5. The package of claim 1, further comprising:
a plurality of signal leads connected to a multiplicity of device contact pads on the semiconductor die, the multiplicity of device contact pads including a gate contact pad, a sense contact pad and at least a source contact pad, the plurality of signal leads extending to an outside of the molded body from a side of the molded body; and
a slot disposed in a top surface of the molded body along the side of the molded body, the slot having a width and a depth to increase a creepage distance to the plurality of signal leads extending to the outside of the molded body from the side of the molded body.

6. The package of claim 1, further comprising:
a pair of cutouts in the molded body extending from a bottom side toward a top side of the molded body, the cutouts forming clamping surfaces along sides of the molded body to clamp the package on a printed circuit board, the pair of cutouts being formed along an axis that is equidistant from a first side and an opposing second side of the molded body.

7. The package of claim 1, wherein the semiconductor die is attached to a die attach pad (DAP) on the substrate with a solder.

8. The package of claim 1, wherein the semiconductor die is attached to a die attach pad (DAP) on the substrate with a silver-based sinter.

9. The package of claim 1, further comprising:
a plurality of signal leads connected to a multiplicity of device contact pads on the semiconductor die, the multiplicity of device contact pads including a gate contact pad and a sense contact pad, the plurality of signal leads extending to an outside of the molded body from a side of the molded body, wherein the gate contact pad and the sense contact pad are wire bonded to a respective pair of signal leads.

10. The package of claim 1, further comprising:
a plurality of signal leads connected to a multiplicity of device contact pads on the semiconductor die, the multiplicity of device contact pads including at least a source contact pad, the plurality of signal leads extending to an outside of the molded body from a side of the molded body, wherein the source contact pad is aluminum wire bonded to a respective group of signal leads.

11. The package of claim 1, further comprising:
a plurality of signal leads connected to a multiplicity of device contact pads on the semiconductor die, the multiplicity of device contact pads including at least a source contact pad, the plurality of signal leads extending to an outside of the molded body from a side of the molded body, wherein the source contact pad is attached to a respective group of signal leads by a direct lead attach (DLA) clip.

12. The package of claim 1, wherein the semiconductor die is a silicon carbide (SiC) power transistor.

13. The package of claim 1, wherein the semiconductor die is a first semiconductor die, and wherein the package comprises a second semiconductor die encapsulated in the molded body, and wherein the first semiconductor die is an insulated-gate bipolar transistor (IGBT), and the second semiconductor die is a fast recovery diode (FRD) or a silicon carbide diode.

14. A package comprising:
a semiconductor die attached to a substrate;
a molded body encapsulating the semiconductor die, wherein the molded body is a six-sided rectangular box-like structure; and
at least a lead attached the semiconductor die, a portion of the lead extending to an outside of the molded body and forming an external terminal of the package, wherein the lead is a drain contact lead and a portion of the drain contact lead extending to the outside of the molded body is notched to reduce a strength of the drain contact lead.

15. The package of claim 14, wherein a top surface of the molded body includes a heat dissipating surface, and wherein the semiconductor die encapsulated in the molded body is thermally coupled to the heat dissipating surface.

16. The package of claim 14, wherein the molded body is a six-sided rectangular box-like structure and at least a corner portion of the molded body formed by two adjacent sides is devoid of molding material reducing a size and a weight of the molded body.

17. A method for fabricating a package, the method comprising:
disposing a semiconductor die on a substrate; and
encapsulating the semiconductor die in a molded body, wherein the molded body is a six-sided rectangular box-like structure and at least a corner portion of the molded body formed by two adjacent sides is devoid of molding material reducing a size and a weight of the molded body.

18. The method of claim 17, further comprising: disposing a heat dissipating surface in a top surface of the molded body; and thermally coupling the semiconductor die encapsulated in the molded body to the heat dissipating surface.

19. The method of claim 17, further comprising:
attaching a drain contact lead to the semiconductor die, a portion of the drain contact lead extending to an outside of the molded body and forming an external terminal of the package; and
notching the portion of the drain contact lead extending to an outside of the molded body to reduce a strength of the drain contact lead.

20. A method for fabricating a package, the method comprising:
disposing a semiconductor die on a substrate;
encapsulating the semiconductor die in a molded body, wherein the molded body is a six-sided rectangular box-like structure;
attaching a drain contact lead to the semiconductor die, a portion of the drain contact lead extending to an outside of the molded body and forming an external terminal of the package; and
notching the portion of the drain contact lead extending to an outside of the molded body to reduce a strength of the drain contact lead.

21. The method of claim 20, further comprising: disposing a heat dissipating surface in a top surface of the molded body; and thermally coupling the semiconductor die encapsulated in the molded body to the heat dissipating surface.

22. The method of claim 20, wherein encapsulating the semiconductor die in the molded body includes excluding mold material from at least a corner portion of the molded body formed by two adjacent sides to reduce a size and a weight of the molded body.
